(19) United States
(12) Patent Application Publication
(10) Pub. No.: US 2016/0246140 A1
(43) Pub. Date: Aug. 25, 2016

(54) ARRAY SUBSTRATE AND DISPLAY DEVICE

(71) Applicant: Shenzhen China Star Optoelectronics Technology Co., Ltd., Shenzhen, Guangdong (CN)

(72) Inventor: Xiangdeng Que, Shenzhen, Guangdong (CN)

(73) Assignee: Shenzhen China Star Optoelectronics Technology Co., Ltd., Shenzhen, Guangdong (CN)

(21) Appl. No.: 14/418,602

(22) PCT Filed: Jan. 19, 2015
(86) PCT No.: PCT/CN2015/070960

§ 371 Date: May 9, 2016

(30) Foreign Application Priority Data
Dec. 26, 2014 (CN) 201410834652.5

(51) Int. Cl. G02F 1/1362; G02F 1/1368; H01L 27/12; G02F 1/1343

(52) U.S. Cl. CPC G02F 1/136213; G02F 1/134309; G02F 1/136286; G02F 1/1368; H01L 27/1255; H01L 27/124; G02F 1/133514

(57) ABSTRACT

An array substrate and a display device are disclosed. The present disclosure relates to the technical field of display, whereby the technical problem that the aperture ratio of the pixel unit is affected by the voltage-dividing capacitor in the prior art can be solved. The array substrate comprises a plurality of pixel units, and each of said pixel units comprises a main pixel region, a sub pixel region, a first voltage-dividing capacitor, a driving scanning line, and a voltage-dividing scanning line, wherein the first voltage-dividing capacitor is formed by a voltage-dividing electrode and the driving scanning line that are arranged in an overlapping manner, or by a voltage-dividing electrode and the voltage-dividing scanning line that are arranged in an overlapping manner.

### CROSS REFERENCE TO RELATED APPLICATION

The present application claims benefit of Chinese patent application CN 201410834652.5, entitled “Array Substrate and Display Device” and filed on Dec. 26, 2014, the entirety of which is incorporated herein by reference.

### FIELD OF THE INVENTION

The present disclosure relates to the technical field of display, and particularly to an array substrate and a display device.

### BACKGROUND OF THE INVENTION

With the development of display technology, the liquid crystal display device has become the most commonly used display device.

The Vertical Alignment (VA) liquid crystal display device is a common liquid crystal display device. At present, in order to eliminate the color shift phenomena under wide viewing angles of the VA liquid crystal display device, each pixel unit can be separated into a main pixel region and a sub pixel region, and additionally provided with a voltage-dividing capacitor.

As shown in FIGS. 1 and 2, a voltage-dividing capacitor Cdown is formed by a part of a common electrode line (Com) 3 and a voltage-dividing electrode 2 that are arranged in an overlapping manner. During display, a first transistor T1 and a second transistor T2 are both turned on by a driving scanning line (Gate1) 11, and a main pixel electrode (not shown in FIG. 1 or 2) in a main pixel region 100 and a sub pixel electrode (not shown in FIG. 1 or 2) in a sub pixel region 200 are charged with a same electric potential by a date line (Data) 4. And then, a third transistor T3 is turned on by a voltage-dividing scanning line (Gate2) 12, and a voltage of the sub pixel electrode is divided by the voltage-dividing capacitor, so that the electric potential of the sub pixel electrode is lower than that of the main pixel electrode. In this case, a brightness of the sub pixel region 200 is slightly lower than that of the main pixel region 100, and a deflection angle of the liquid crystal molecules in the main pixel region 100 is different from that in the sub pixel region 200. Therefore, the color shift phenomena under wide viewing angles of the VA liquid crystal display device can be alleviated.

However, since the common electrode line 3 and the voltage-dividing electrode 2 are both made of metal materials, an aperture ratio of the pixel unit would be affected by the voltage-dividing capacitor. Especially under the development trend that the resolution is becoming increasingly high, and the area of the pixel unit is becoming increasingly small nowadays, the influence of the traditional voltage-dividing capacitor on the aperture ratio is becoming more obvious.

### SUMMARY OF THE INVENTION

The purpose of the present disclosure is to provide an array substrate and a display device so as to solve the technical problem that the aperture ratio of the pixel unit is affected by the voltage-dividing capacitor in the prior art.

The present disclosure provides an array substrate, which comprises a plurality of pixel units, and each of said pixel units comprises a main pixel region, a sub pixel region, a first voltage-dividing capacitor, a driving scanning line, and a voltage-dividing scanning line,

wherein said first voltage-dividing capacitor is formed by a voltage-dividing electrode and said driving scanning line that are arranged in an overlapping manner, or by a voltage-dividing electrode and said voltage-dividing scanning line that are arranged in an overlapping manner.

Further, said pixel unit further comprises a second voltage-dividing capacitor and a common electrode line; and said second voltage-dividing capacitor is formed by said voltage-dividing electrode and said common electrode line that are arranged in an overlapping manner.

Preferably, said driving scanning line, said voltage-dividing scanning line and said common electrode line are arranged in a same layer during patterning.

Further, said pixel unit further comprises a data line, and said voltage-dividing electrode and said data line are arranged in a same layer during patterning.

Further, said pixel unit is further provided with a first transistor, a second transistor, and a third transistor;

wherein a gate of said first transistor is connected with said driving scanning line, a source thereof is connected with said data line, and a drain thereof is connected with a main pixel electrode in said main pixel region;

wherein a gate of said second transistor is connected with said driving scanning line, a source thereof is connected with said data line, and a drain thereof is connected with a sub pixel electrode in said sub pixel region; and

wherein a gate of said third transistor is connected with said voltage-dividing scanning line, a source thereof is connected with said sub pixel electrode, and a drain thereof is connected with said voltage-dividing electrode.

Preferably, the drain of said third transistor is integrated with said voltage-dividing electrode.

The present disclosure further provides a display device, which comprises a color filter substrate and the aforesaid array substrate.

Preferably, said display device is a vertical alignment display device.

The following beneficial effects can be brought about according to the present disclosure. In the array substrate according to the present disclosure, the first voltage-dividing capacitor of the pixel unit is formed by the voltage-dividing electrode and the driving scanning line that are arranged in an overlapping manner, or by the voltage-dividing electrode and the voltage-dividing scanning line that are arranged in an overlapping manner, rather than by the voltage-dividing electrode and the common electrode line that are arranged in an overlapping manner. In this manner, the area of the common electrode line in the pixel unit can be reduced, while the area of the driving scanning line and that of the voltage-dividing scanning line will not be increased. Therefore, the aperture ratio of the pixel unit can be improved, and thus the technical problem that the aperture ratio of the pixel unit is affected by the voltage-dividing capacitor in the prior art can be solved.

Other features and advantages of the present disclosure will be further explained in the following description, and partially become self-evident therefrom, or be understood through the embodiments of the present disclosure. The objectives and advantages of the present disclosure will be achieved through the structure specifically pointed out in the description, claims, and the accompanying drawings.

### BRIEF DESCRIPTION OF THE DRAWINGS

The drawings necessary for explaining the embodiments according to the present disclosure are introduced briefly below to illustrate the technical solutions of these embodiments more clearly.

FIG. 1 is a schematic diagram of a pixel unit in an array substrate in the prior art;

FIG. 2 is a circuit diagram of the pixel unit in the array substrate in the prior art;

FIG. 3 is a schematic diagram of a pixel unit in an array substrate provided by Embodiment 1 of the present disclosure;

FIG. 4 is a circuit diagram of the pixel unit in the array substrate provided by Embodiment 1 of the present disclosure;

FIG. 5 is a schematic diagram of a pixel unit in an array substrate according to another example provided by Embodiment 1 of the present disclosure;

FIG. 6 is a circuit diagram of the pixel unit in the array substrate according to another example provided by Embodiment 1 of the present disclosure;

FIG. 7 is a schematic diagram of a pixel unit in an array substrate provided by Embodiment 2 of the present disclosure;

FIG. 8 is a circuit diagram of the pixel unit in the array substrate provided by Embodiment 2 of the present disclosure;

FIG. 9 is a schematic diagram of a pixel unit in an array substrate according to another example provided by Embodiment 2 of the present disclosure; and

FIG. 10 is a circuit diagram of the pixel unit in the array substrate according to another example provided by Embodiment 2 of the present disclosure.

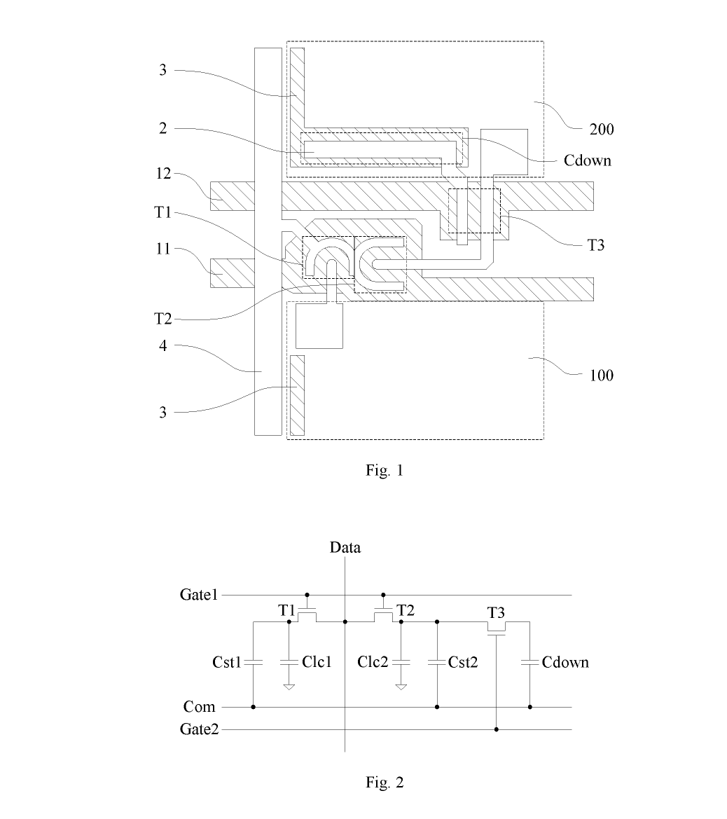

### DETAILED DESCRIPTION OF THE EMBODIMENTS

The present disclosure will be explained in details with reference to the embodiments and the accompanying drawings, whereby it can be fully understood how to solve the technical problem by the technical means according to the present disclosure and achieve the technical effects thereof, and thus the technical solution according to the present disclosure can be implemented. It should be noted that, as long as there is no structural conflict, all the technical features mentioned in all the embodiments may be combined together in any manner, and the technical solutions obtained in this manner all fall within the scope of the present disclosure.

### Embodiment 1

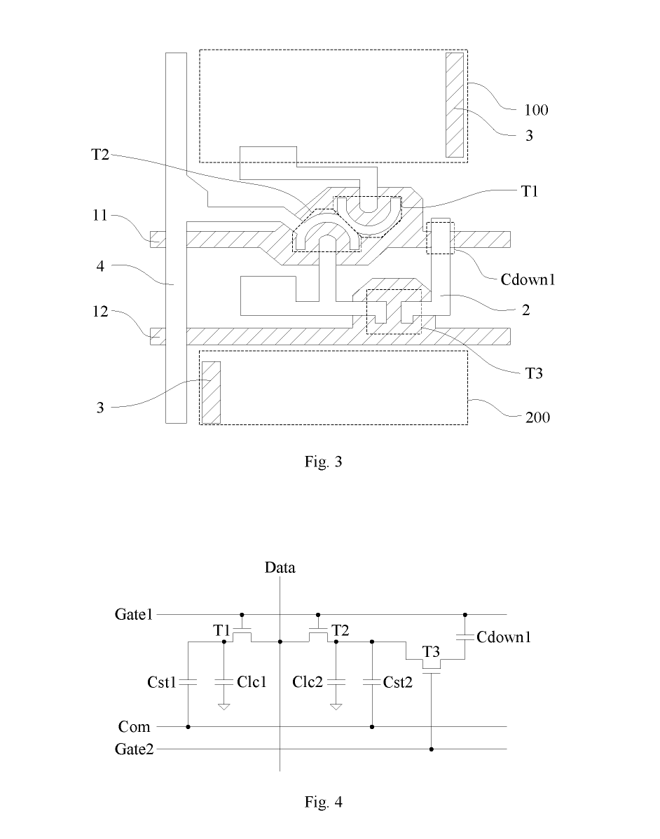

The embodiment of the present disclosure provides an array substrate, which comprises a plurality of pixel units and can be used in VA liquid crystal display device. As shown in FIGS. 3 and 4, a pixel unit comprises a main pixel region 100, a sub pixel region 200, a first voltage-dividing capacitor Cdown1, a driving scanning line (Gate1) 11, and a voltage-dividing scanning line (Gate2) 12. The main pixel region 100 is provided with a main pixel electrode (not shown in FIG. 3 or 4), and the sub pixel region 200 is provided with a sub pixel electrode (not shown in FIG. 3 or 4).

According to the present embodiment, the first voltage-dividing capacitor is formed by a voltage-dividing electrode 2 and the driving scanning line 11 that are arranged in an overlapping manner. During display, a scanning is performed row by row by the driving scanning line 11 of the pixel unit in each row. Hence, at any moment, only one driving scanning line 11 has a high-level voltage. Moreover, a time period during which any driving scanning line 11 has the high-level voltage is rather short. That is, any driving scanning line 11 always has a low-level voltage almost. Therefore, the first voltage-dividing capacitor, which is formed by the voltage-dividing electrode 2 and the driving scanning line 11 that are arranged in an overlapping manner, can play the role of voltage-dividing on the sub pixel electrode satisfactorily. In this case, a brightness of the sub pixel region is slightly lower than that of the main pixel region, and a deflection angle of the liquid crystal molecules in the main pixel region is different from that in the sub pixel region. Therefore, the color shift phenomena under wide viewing angles of the VA liquid crystal display device can be alleviated.

According to the present embodiment, the pixel unit further comprises a common electrode line (Com) 3, a data line (Data) 4, a first transistor T1, a second transistor T2, and a third transistor T3.

In this structure, a gate of T1 is connected with the driving scanning line 11, a source thereof is connected with the data line 4, and a drain thereof is connected with the main pixel electrode. In the main pixel region 100, a main storage capacitor Cst1 is formed between the main pixel electrode and the common electrode line 3, and a main liquid crystal capacitor Clc1 is formed between the main pixel electrode and a common electrode of the color filter substrate.

A gate of T2 is connected with the driving scanning line 11, a source thereof is connected with the data line 4, and a drain thereof is connected with the sub pixel electrode. In the sub pixel region 200, a sub storage capacitor Cst2 is formed between the sub pixel electrode and the common electrode line 3, and a sub liquid crystal capacitor Clc2 is formed between the sub pixel electrode and the common electrode of the color filter substrate.

A gate of T3 is connected with the voltage-dividing scanning line 12, a source thereof is connected with the sub pixel electrode, and a drain thereof is connected with the voltage-dividing electrode 2. The first voltage-dividing capacitor is formed between the voltage-dividing electrode 2 and the driving scanning line 11.

As a preferred solution, the driving scanning line 11, the voltage-dividing scanning line 12 and the common electrode line 3 are arranged in a same layer during patterning, and the voltage-dividing electrode 2 and the data line 4 are arranged in a same layer during patterning. During the manufacturing of the array substrate, the driving scanning line 11, the voltage-dividing scanning line 12 and the common electrode line 3 can be formed through one single patterning procedure, and the voltage-dividing electrode 2 and the data line 4 can also be formed through one single patterning procedure. In this case, the manufacturing of the array substrate can be simplified. Since the sources and drains of T1, T2, and T3 and the data line are arranged in a same layer during patterning, as a further preferred solution, the drain of T3 can be integrated with the voltage-dividing electrode.

During display, the driving scanning line 11 is firstly turned on, while the voltage-dividing scanning line 12 is turned off, so that T1 and T2 are both turned on, while T3 is turned off. At the same time, the main pixel electrode and the sub pixel electrode are charged with a same data voltage by the data line 4 through T1 and T2 respectively, and thus Clc1, Cst1, Clc2, and Cst2 all have a same voltage. And then, the driving scanning line 11 is turned off, while the voltage-dividing scanning line 12 is turned on, so that T1 and T2 are both turned off, while T3 is turned on. A voltage of the sub pixel electrode is divided by Cdown1 through T3, and thus the data voltage of the sub pixel electrode can be reduced. Therefore, the voltage of Clc2 and Cst2 can be reduced, while the voltage of Clc1 and Cst1 is not changed. In this case, the voltage of Clc2 is lower than that of Clc1, so that the brightness of the sub pixel region is slightly lower than that of the main pixel region, and the deflection angle of the liquid crystal molecules in the main pixel region is different from that in the sub pixel region. Hence, the color shift phenomena under wide viewing angles of the VA liquid crystal display device can be alleviated.

In the array substrate according to the embodiment of the present disclosure, the first voltage-dividing capacitor of the pixel unit is formed by the voltage-dividing electrode 2 and the driving scanning line 11 that are arranged in an overlapping manner, rather than by the voltage-dividing electrode 2 and the common electrode line 3 that are arranged in an overlapping manner. In this case, the area of the common electrode line 3 in the pixel unit can be reduced, while the area of the driving scanning line 11 is not increased. Therefore, the aperture ratio of the pixel unit can be improved, and thus the technical problem that the aperture ratio of the pixel unit is affected by the voltage-dividing capacitor in the prior art can be solved.

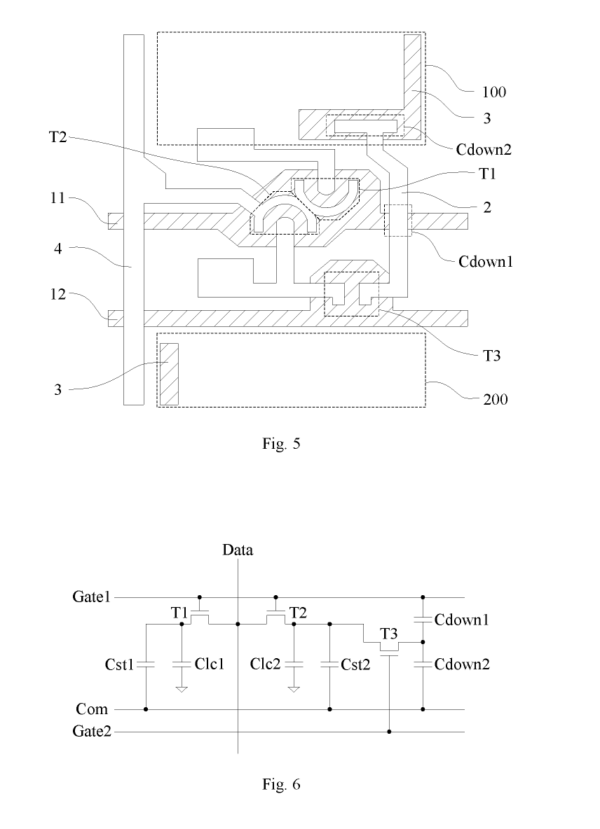

According to another example, the pixel unit may further comprise a second voltage-dividing capacitor Cdown2, as shown in FIGS. 5 and 6. The second voltage-dividing capacitor is formed by the voltage-dividing electrode 2 and the common electrode line 3 that are arranged in an overlapping manner. The voltage of the sub pixel electrode can be divided by the first voltage-dividing capacitor and the second voltage-dividing capacitor, so that the voltage of the sub pixel electrode can be further reduced, and the color shift phenomena under wide viewing angles of the VA liquid crystal display device can be alleviated to a greater extent.

Of course, the area of the common electrode line 3 which is used for forming the second voltage-dividing capacitor is also small. Compared with the prior art, the area of the common electrode line 3 can be still reduced significantly. Therefore, the aperture ratio of the pixel unit can be improved, and thus the technical problem that the aperture ratio of the pixel unit is affected by the voltage-dividing capacitor in the prior art can be solved.

### Embodiment 2

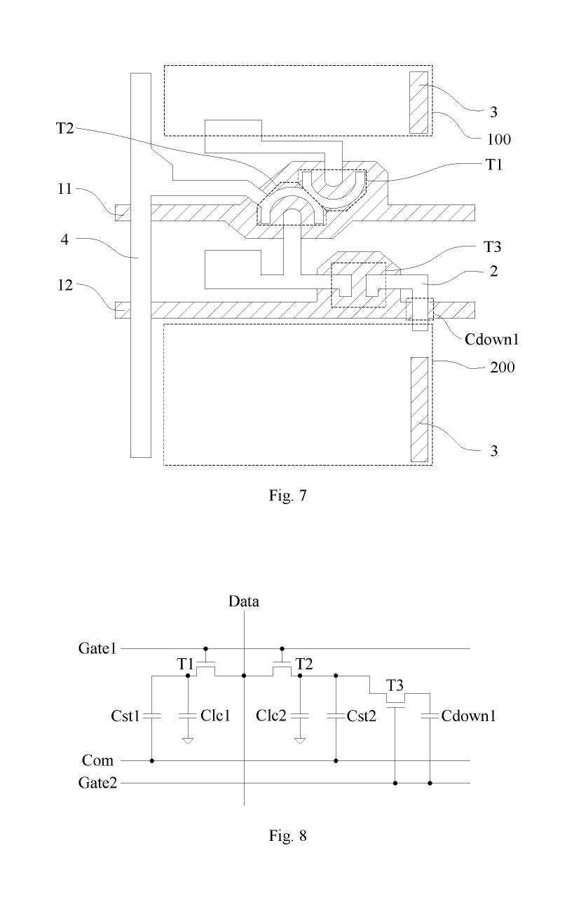

The embodiment of the present disclosure provides an array substrate, which comprises a plurality of pixel units and can be used in VA liquid crystal display device. As shown in FIGS. 7 and 8, a pixel unit comprises a main pixel region 100, a sub pixel region 200, a first voltage-dividing capacitor Cdown1, a driving scanning line (Gate1) 11, and a voltage-dividing scanning line (Gate2) 12. The main pixel region 100 is provided with a main pixel electrode (not shown in FIG. 7 or 8), and the sub pixel region 200 is provided with a sub pixel electrode (not shown in FIG. 7 or 8).

According to the present embodiment, the first voltage-dividing capacitor is formed by a voltage-dividing electrode 2 and the voltage-dividing scanning line 12 that are arranged in an overlapping manner. During display, a scanning is performed row by row by the voltage-dividing scanning line 12 of the pixel unit in each row. Hence, at any moment, only one voltage-dividing scanning line 12 has a high-level voltage. Moreover, a time period during which any voltage-dividing scanning line 12 has the high-level voltage is rather short. That is, any voltage-dividing scanning line 12 always has a low-level voltage almost. Therefore, the first voltage-dividing capacitor, which is formed by the voltage-dividing electrode 2 and the voltage-dividing scanning line 12 that are arranged in an overlapping manner, can play the role of voltage-dividing on the sub pixel electrode satisfactorily. In this case, a brightness of the sub pixel region is slightly lower than that of the main pixel region, and a deflection angle of the liquid crystal molecules in the main pixel region is different from that in the sub pixel region. Therefore, the color shift phenomena under wide viewing angles of the VA liquid crystal display device can be alleviated.

According to the present embodiment, the pixel unit further comprises a common electrode line (Com) 3, a data line (Data) 4, a first transistor T1, a second transistor T2, and a third transistor T3.

In this structure, a gate of T1 is connected with the driving scanning line 11, a source thereof is connected with the data line 4, and a drain thereof is connected with the main pixel electrode. In the main pixel region 100, a main storage capacitor Cst1 is formed between the main pixel electrode and the common electrode line 3, and a main liquid crystal capacitor Clc1 is formed between the main pixel electrode and a common electrode of the color filter substrate.

A gate of T2 is connected with the driving scanning line 11, a source thereof is connected with the data line 4, and a drain thereof is connected with the sub pixel electrode. In the sub pixel region 200, a sub storage capacitor Cst2 is formed between the sub pixel electrode and the common electrode line 3, and a sub liquid crystal capacitor Clc2 is formed between the sub pixel electrode and the common electrode of the color filter substrate.

A gate of T3 is connected with the voltage-dividing scanning line 12, a source thereof is connected with the sub pixel electrode, and a drain thereof is connected with the voltage-dividing electrode 2. The first voltage-dividing capacitor is formed between the voltage-dividing electrode 2 and the voltage-dividing scanning line 12.

As a preferred solution, the driving scanning line 11, the voltage-dividing scanning line 12 and the common electrode line 3 are arranged in a same layer during patterning, and the voltage-dividing electrode 2 and the data line 4 are arranged in a same layer during patterning. During the manufacturing of the array substrate, the driving scanning line 11, the voltage-dividing scanning line 12 and the common electrode line 3 can be formed through one single patterning procedure, and the voltage-dividing electrode 2 and the data line 4 can also be formed through one single patterning procedure. In this case, the manufacturing of the array substrate can be simplified. Since the sources and drains of T1, T2, and T3 and the data line are arranged in a same layer during patterning, as a further preferred solution, the drain of T3 can be integrated with the voltage-dividing electrode.

During display, the driving scanning line 11 is firstly turned on, while the voltage-dividing scanning line 12 is turned off, so that T1 and T2 are both turned on, while T3 is turned off. At the same time, the main pixel electrode and the sub pixel electrode are charged with a same data voltage by the data line 4 through T1 and T2 respectively, and thus Clc1, Cst1, Clc2, and Cst2 all have a same voltage. And then, the driving scanning line 11 is turned off, while the voltage-dividing scanning line 12 is turned on, so that T1 and T2 are both turned off, while T3 is turned on. A voltage of the sub pixel electrode is divided by Cdown1 through T3, and thus the data voltage of the sub pixel electrode can be reduced. Therefore, the voltage of Clc2 and Cst2 can be reduced, while the voltage of Clc1 and Cst1 is not changed. In this case, the voltage of Clc2 is lower than that of Clc1, so that the brightness of the sub pixel region is slightly lower than that of the main pixel region, and the deflection angle of the liquid crystal molecules in the main pixel region is different from that in the sub pixel region. Hence, the color shift phenomena under wide viewing angles of the VA liquid crystal display device can be alleviated.

In the array substrate according to the embodiment of the present disclosure, the first voltage-dividing capacitor of the pixel unit is formed by the voltage-dividing electrode 2 and the voltage-dividing scanning line 12 that are arranged in an overlapping manner, rather than by the voltage-dividing electrode 2 and the common electrode line 3 that are arranged in an overlapping manner. In this case, the area of the common electrode line 3 in the pixel unit can be reduced, while the area of the voltage-dividing scanning line 12 is not increased. Therefore, the aperture ratio of the pixel unit can be improved, and thus the technical problem that the aperture ratio of the pixel unit is affected by the voltage-dividing capacitor in the prior art can be solved.

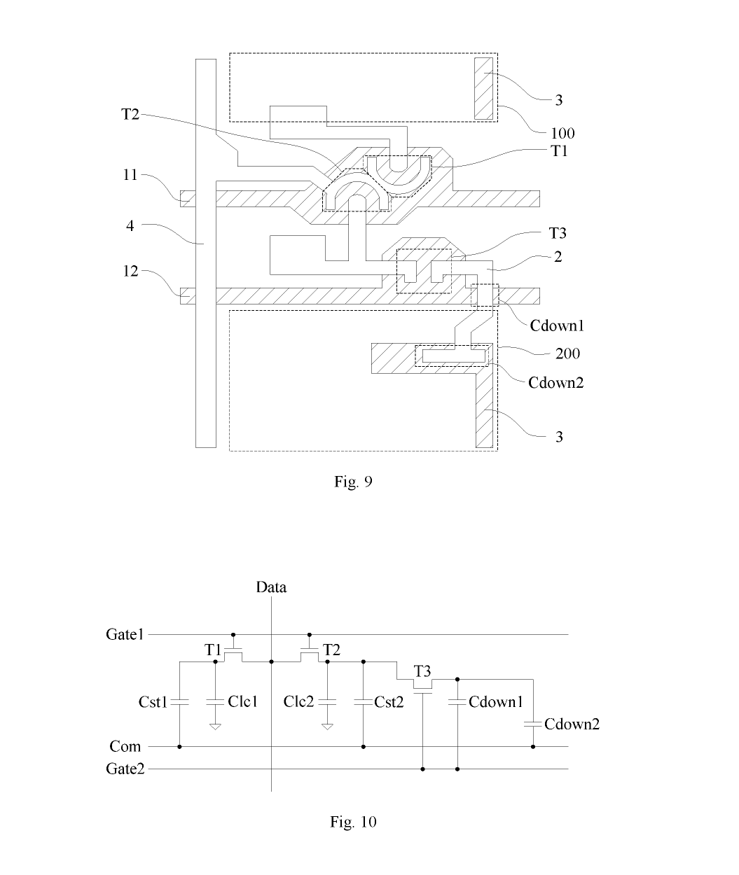

According to another example, the pixel unit may further comprise a second voltage-dividing capacitor Cdown2, as shown in FIGS. 9 and 10. The second voltage-dividing capacitor is formed by the voltage-dividing electrode 2 and the common electrode line 3 that are arranged in an overlapping manner. The voltage of the sub pixel electrode can be divided by the first voltage-dividing capacitor and the second voltage-dividing capacitor, so that the voltage of the sub pixel electrode can be further reduced, and the color shift phenomena under wide viewing angles of the VA liquid crystal display device can be alleviated to a greater extent.

Of course, the area of the common electrode line 3 which is used for forming the second voltage-dividing capacitor is also small. Compared with the prior art, the area of the common electrode line 3 can be still reduced significantly. Therefore, the aperture ratio of the pixel unit can be improved, and thus b.

### Embodiment 3

The embodiment of the present disclosure provides a display device, and preferably a VA display device, which can specifically be liquid crystal TV, liquid crystal display device, mobile phone, tablet personal computer, etc. The display device comprises a color filter substrate and the array substrate according to the embodiments of the present disclosure.

Since the display device provided by the embodiment of the present disclosure has the same technical features as the array substrate provided by the above Embodiment 1 or Embodiment 2, they can solve the same technical problem and achieve the same technical effect.

The above embodiments are described only for better understanding, rather than restricting, the present disclosure. Any person skilled in the art can make amendments to the implementing forms or details without departing from the spirit and scope of the present disclosure. The protection scope of the present disclosure shall be determined by the scope as defined in the claims.

1. An array substrate, comprising a plurality of pixel units, each of said pixel units comprising a main pixel region, a sub pixel region, a first voltage-dividing capacitor, a driving scanning line, and a voltage-dividing scanning line,
wherein said first voltage-dividing capacitor is formed by a voltage-dividing electrode and said driving scanning line that are arranged in an overlapping manner, or by a voltage-dividing electrode and said voltage-dividing scanning line that are arranged in an overlapping manner.

2. The array substrate according to claim 1, wherein said pixel unit further comprises a second voltage-dividing capacitor and a common electrode line; and
wherein said second voltage-dividing capacitor is formed by said voltage-dividing electrode and said common electrode line that are arranged in an overlapping manner.

3. The array substrate according to claim 2, wherein said driving scanning line, said voltage-dividing scanning line and said common electrode line are arranged in a same layer during patterning.

4. The array substrate according to claim 1, wherein said pixel unit further comprises a data line, and said voltage-dividing electrode and said data line are arranged in a same layer during patterning.

5. The array substrate according to claim 4, wherein said pixel unit is further provided with a first transistor, a second transistor, and a third transistor;
wherein a gate of said first transistor is connected with said driving scanning line, a source thereof is connected with said data line, and a drain thereof is connected with a main pixel electrode in said main pixel region;
wherein a gate of said second transistor is connected with said driving scanning line, a source thereof is connected with said data line, and a drain thereof is connected with a sub pixel electrode in said sub pixel region; and
wherein a gate of said third transistor is connected with said voltage-dividing scanning line, a source thereof is connected with said sub pixel electrode, and a drain thereof is connected with said voltage-dividing electrode.

6. The array substrate according to claim 5, wherein the drain of said third transistor is integrated with said voltage-dividing electrode.

7. A display device, comprising a color filter substrate and an array substrate,
wherein said array substrate comprises a plurality of pixel units, and each of said pixel units comprises a main pixel region, a sub pixel region, a first voltage-dividing capacitor, a driving scanning line, and a voltage-dividing scanning line; and
wherein said first voltage-dividing capacitor is formed by a voltage-dividing electrode and said driving scanning line that are arranged in an overlapping manner, or by a voltage-dividing electrode and said voltage-dividing scanning line that are arranged in an overlapping manner.

8. The display device according to claim 7, wherein said pixel unit further comprises a second voltage-dividing capacitor and a common electrode line; and
wherein said second voltage-dividing capacitor is formed by said voltage-dividing electrode and said common electrode line that are arranged in an overlapping manner.

9. The display device according to claim 8, wherein said driving scanning line, said voltage-dividing scanning line and said common electrode line are arranged in a same layer during patterning.

10. The display device according to claim 7, wherein said pixel unit further comprises a data line, and said voltage-dividing electrode and said data line are arranged in a same layer during patterning.

11. The display device according to claim 10, wherein said pixel unit is further provided with a first transistor, a second transistor, and a third transistor;
wherein a gate of said first transistor is connected with said driving scanning line, a source thereof is connected with said data line, and a drain thereof is connected with a main pixel electrode in said main pixel region;
wherein a gate of said second transistor is connected with said driving scanning line, a source thereof is connected with said data line, and a drain thereof is connected with a sub pixel electrode in said sub pixel region; and
wherein a gate of said third transistor is connected with said voltage-dividing scanning line, a source thereof is connected with said sub pixel electrode, and a drain thereof is connected with said voltage-dividing electrode.

12. The display device according to claim 11, wherein the drain of said third transistor is integrated with said voltage-dividing electrode.

13. The display device according to claim 7, wherein said display device is a vertical alignment display device.
